(19) United States
(12) Patent Application Publication
(10) Pub. No.: US 2003/0011992 A1
(43) Pub. Date: Jan. 16, 2003

(54) HEAT DISSIPATION APPARATUS

(76) Inventors: Dah-Chyi Kuo, Sanchung City (TW); Chian Tao, Sanchung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/894,144

(22) Filed: Jun. 29, 2001

(51) Int. Cl. H05K 7/20

(52) U.S. Cl. 361/704

(57) ABSTRACT

A heat dissipater comprises a heat expansion device having a cavity; and a heat transfer medium filled in the cavity, wherein the heat transfer medium is paraffin, water, methanol, mercury, etc. When heat expansion device is in contact with a heat source, heat is transferred to the heat transfer medium so that heat transfer medium is heated gradually to generate heat convection; and then heat is transferred to other positions of the heat expansion device so that heat is expanded.

### FIELD OF THE INVENTION

The present invention relates to a heat dissipater, and especially to a heat dissipating structure with a lower cost and a better heat convection effect.

### BACKGROUND OF THE INVENTION

In the prior art, there are many kinds of heat dissipating structures which are mainly used in the heat dissipation of electronic elements. These elements are primarily used to dissipate heat generated from electronic elements. Referring to FIG. 1, in the heat source of an electronic element, heat is lead out by a heat guide block 1. In some structures, a fin structure is directly formed on the heat guide block. In another form, a heat pipe 2 is installed in the heat guide block 1. A heat dissipating fin set 11 at another end of the heat pipe 2 has the function of heat dissipation. The heat pipe 2 is a medium for transferring heat. Heat is transferred to the fins 111 of the heat dissipater 10. The structure of the heat pipe 2 is a closing tube 20 filling with liquid 22. In the heat source, the heat tube 2 absorbs heat and then vaporized. The heat transfers to the heat dissipater 10 and then the liquid condenses. To quick the circulation of the liquid, a wick structure 21 is installed. The wick structure absorbs the condensed liquid 22 rapidly. Since heat pipe 2 has a preferred heat conductivity. However, the manufacturing process has many steps. The cost is high.

### SUMMARY OF THE INVENTION

Accordingly, the primary object of the present invention is to provide a heat dissipater, wherein heat is dissipated integrally so that as heat can be transferred out by heat convection This way of heat convection is slower than the heat tube, but the cost in manufacturing is decreased and has a satisfactory heat transferred effect.

A further object of the present invention is to provide a heat dissipater comprising a heat expansion device having a cavity; and a heat transfer medium filled in the cavity, wherein the heat transfer medium is paraffin, water, methanol, mercury, etc. When heat expansion device is in contact with a heat source, heat is transferred to the heat transfer medium so that heat transfer medium is heated gradually to generate heat convection; and then heat is transferred to other positions of the heat expansion device so that heat is expanded.

The various objects and advantages of the present invention will be more readily understood from the following detailed description when read in conjunction with the appended drawing.

### BRIEF DESCRIPTION OF THE DRAWINGS

FIG. 1 is a cross sectional view of the prior art.

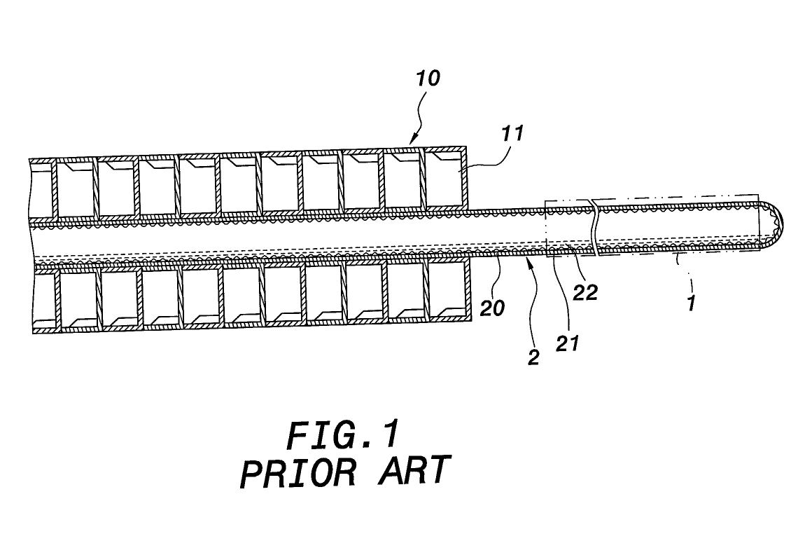

FIG. 2 is a perspective view of the plate shape of the present invention.

FIG. 3 is a cross sectional view of FIG. 2 of the present invention.

FIG. 4 is a schematic view of the heat transfer of FIG. 3 in the present invention.

FIG. 5 is a perspective view of the tube form of the present invention.

FIG. 6 is a cross sectional view of the FIG. 5 of the present invention.

FIG. 7 is a perspective view showing a combining type of the present invention.

FIG. 8 is a cross sectional view of FIG. 7.

### DETAILED DESCRIPTION OF THE PREFERRED EMBODIMENTS

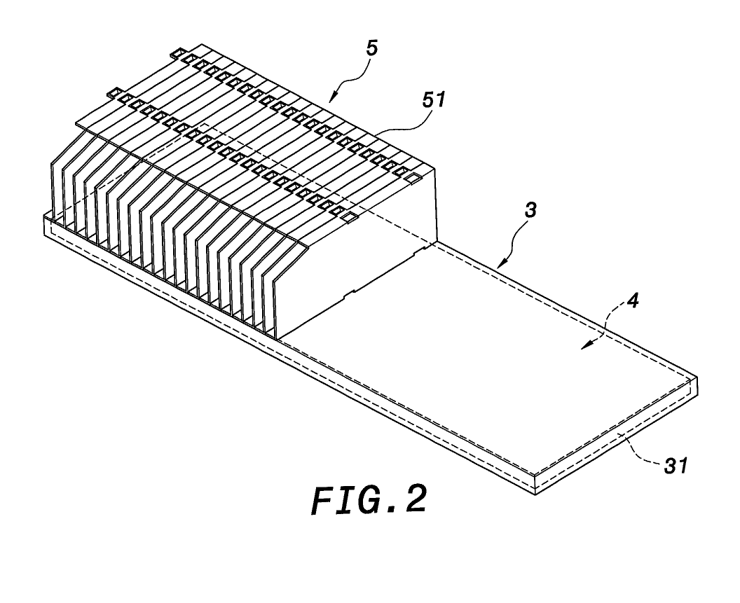

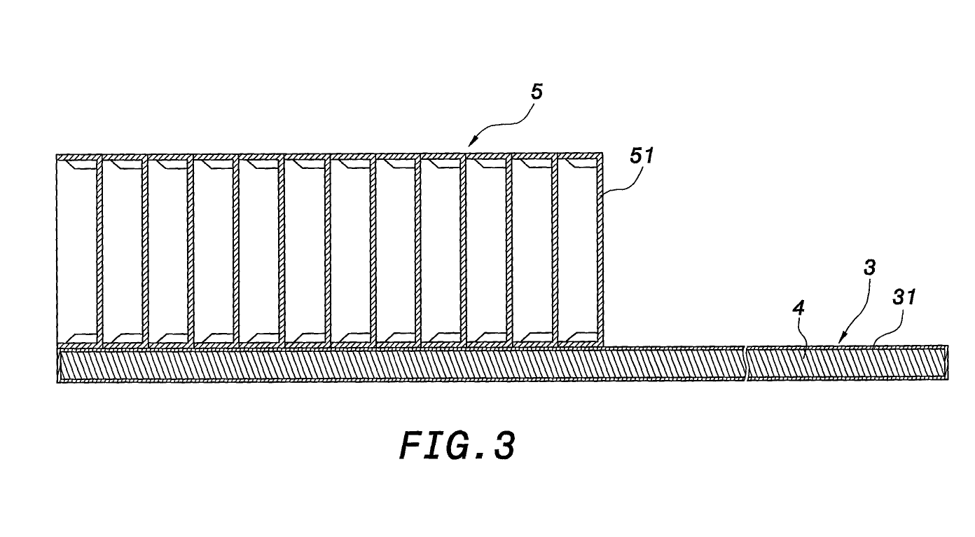

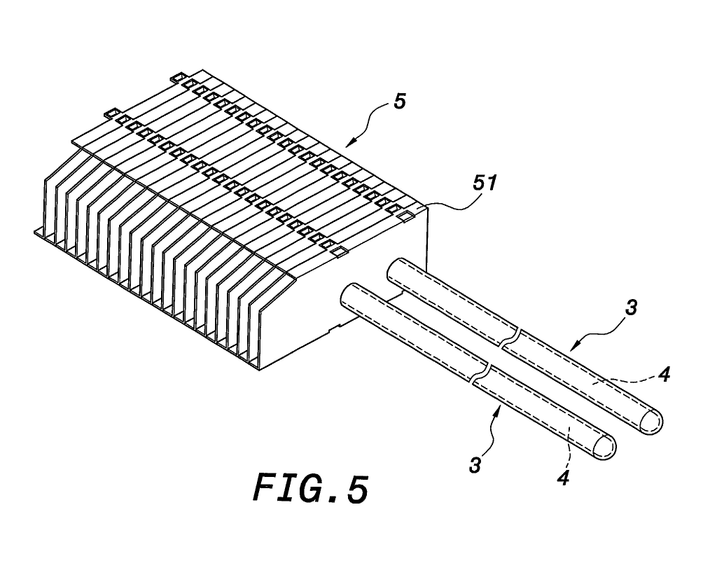

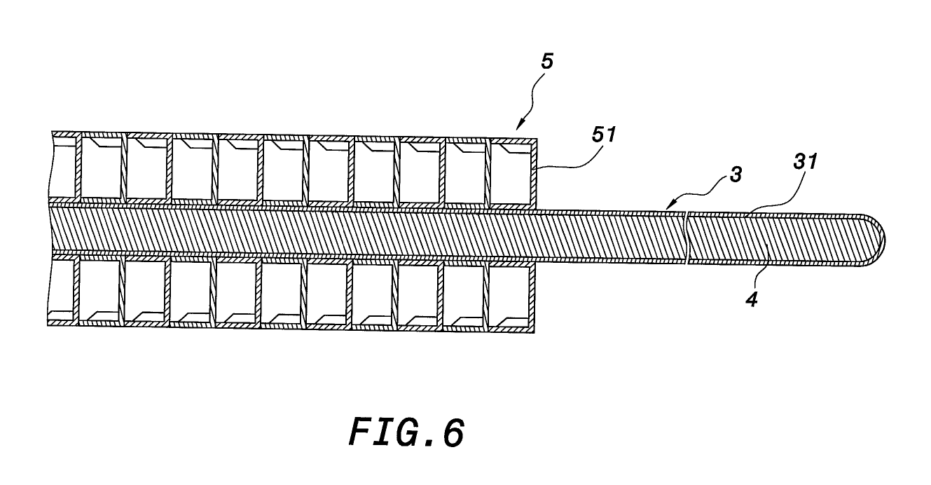

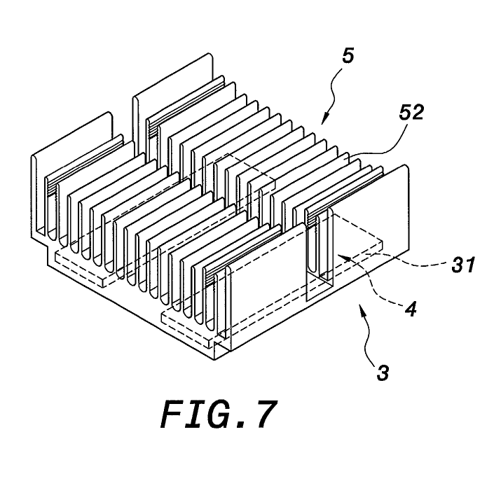

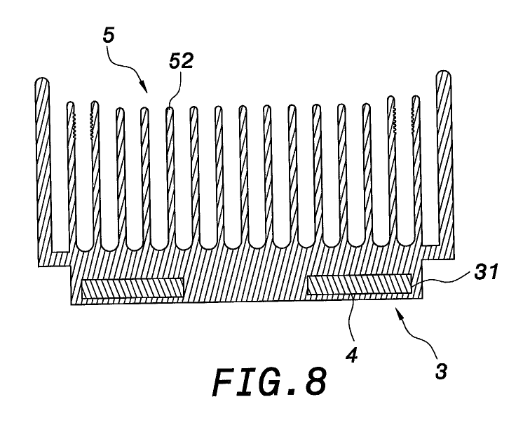

Referring to FIGS. 2 and 3, a plate shape form of the heat dissipater of the present invention is illustrated. FIGS. 5 and 6 show a tube form embodiment. FIGS. 7 and 8 are a combination form. These three forms have the same structures, but the outer shapes are different. The heat dissipater has a heat expansion device 3. The heat expansion device 3 has a cavity 31 therein. The cavity 31 is filled with heat transfer medium 4. The heat expansion device 3 is made of material with preferred conductivity, such as aluminum, copper, or other metal. The heat transfer medium 4 has a solid form in normal temperature (below 30 degree C., preferably 20˜30 degree C.), such as wax, or liquid material in normal temperature, such as paraffin oil, water, methanol, mercury, etc. When the heat expansion device 3 is in contact with the heat source 6. The heat of the heat source 6 will be transferred to the heat transfer medium 4 so that the heat transfer medium 4 is heated gradually, and thus heat convection occurs. Then heat is transferred to other positions of the heat expansion device 3 so to expand. The heat expansion device 3 is connected with a plurality of heat dissipating element 5. In the plate and tube heat dissipater, the heat dissipating element 5 is installed with heat dissipating fins 51. The heat dissipating fins 52 are directly formed with the heat expansion device 3 integrally so as to be formed with an array or bank shape structure so that heat is dissipated from the surface of the heat dissipating fins.

The most important structure of the present invention is that the heat transfer medium is installed at the heat expansion device. In the prior art, the heat transfer medium is heat tube for transferring heat rapidly. In the present invention, the heat transfer medium is a material with lower cost. In the following, In the following, wax is used as a description. The wax will be melted into liquid, as temperature is above 40 degree C. Therefore, in normal temperature of 25 degree C., wax is a block shape solid. Thus, in normal temperature of 25 degree C., wax can have any shape.

When cavities are installed in the heat expansion device, heat melting material can be filled into the cavity so as to fill the cavity completely. In general, the heat transfer medium is arranged at in a heat conductive device independently and has material different from the heat expanding device.

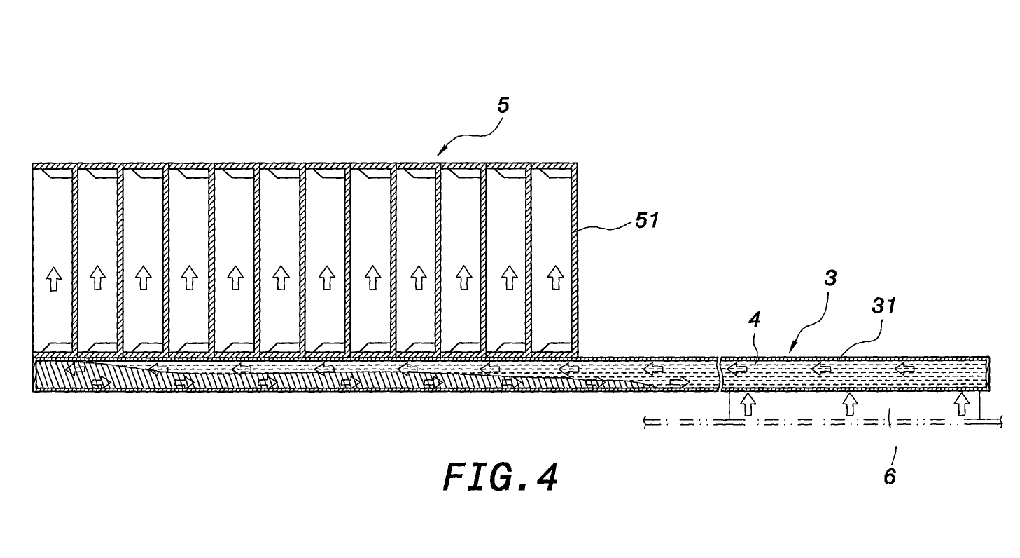

Referring to FIG. 4, the heat transfer medium, wax, near the heat source will heat and thus melted since wax will dissolve above 40 degrees, while a part of wax not heated will cool rapidly. Since initially, the heat source has a lower temperature. Therefore, the condition illustrated in Fig. Occurs. The energy of heat source will transfer to the heat transfer medium continuously so that the heat transfer medium is converted into liquid wax. The liquid from melting wax will generate heat convention so that heat will transfer continuously from the heat source to the heat transfer element. Initially, the melting effect is bad, but the condition will change with the temperature increasing of heat source. Since no gasify space is formed in the heat conductive device, the heat convection of liquid is finite.

For liquid, such as water, methanol, mercury in normal temperature, the cavity must be installed with a filling opening. The preset space of the cavity is conformed to the filling opening. The opening is sealed properly for assuring that the cavity is filled with liquid heat transfer medium. Therefore, the liquid heat transfer medium has the function of heat convection.

In summary, the heat convection of the heat transfer medium 4 of the present invention is superior than the heat expansion device and can be combined with the heat expansion device so that the cost in the manufacturing process can be saved. The commercial of the product is increased, thereby, the heat transfer medium generating heat convection effect in the heat expansion device. Therefore, heat can be transferred rapidly and thus a good utility is provided. Thus, it is a device completely from the prior art.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat dissipater comprising:
a heat expansion device having a cavity; and
a heat transfer medium filled in the cavity;
when heat expansion device is in contact with a heat source, heat is transferred to the heat transfer medium so that heat transfer medium is heated gradually to generate heat convection; and then heat is transferred to other positions of the heat expansion device so that heat is expanded.

2. The heat dissipater as claimed in claim 1, wherein the heat transfer medium is a solid material in normal temperature.

3. The heat dissipater as claimed in claim 2, wherein the heat transfer medium is wax.

4. The heat dissipater as claimed in claim 1, wherein the heat transfer medium is liquid material in normal temperature.

5. The heat dissipater as claimed in claim 4, wherein the heat transfer medium is paraffin, water, methanol, or mercury.
